(19) United States
(12) Patent Application Publication
(10) Pub. No.: US 2026/0025994 A1
(43) Pub. Date: Jan. 22, 2026

(54) FLASH MEMORY CELL AND THREE-DIMENSIONAL FLASH MEMORY DEVICE HAVING THE SAME

(71) Applicant: Winbond Electronics Corp., Taichung City (TW)

(72) Inventor: Frederick CHEN, Tainan City (TW)

(73) Assignee: Winbond Electronics Corp., Taichung City (TW)

(21) Appl. No.: 18/777,130

(22) Filed: Jul. 18, 2024

(51) Int. Cl. H10B 43/27; H01L 23/528; H01L 29/423; H10B 43/10

(52) U.S. Cl. CPC H10B 43/27; H01L 23/5283; H10B 43/10; H10D 30/696

(57) ABSTRACT

A flash memory cell includes a channel structure, a first gate, a second gate, a storage structure, a source line pillar and a bit line pillar. The channel structure is formed over a substrate. The first gate is formed adjacent to the channel structure. The second gate is separated from the first gate and the channel structure. The storage structure is adjacent to the channel structure. The source line pillar and the bit line pillar are respectively adjacent to opposite sidewalls of the channel structure. The first gate does not vertically overlap with the channel structure.

### BACKGROUND OF THE INVENTION

### Field of the Invention

The present invention relates to a memory structure and a three-dimensional (3D) memory device having the same, and, in particular, to a flash memory cell and a 3D flash memory device having the same.

### Description of the Related Art

Current NOR flash memory devices with stacked-gate have slow programming and erasing speeds. To improve the operation speed of the flash memory, a split-gate flash memory with efficient programming and erasing speeds is developed. However, split-gate flash memory has a larger cell size, thereby reducing the integration density of the memory cells. Thus, there is a trade-off between the operation speed and the integration density of flash memory.

### BRIEF SUMMARY OF THE INVENTION

Accordingly, the present disclosure provides a flash memory cell and a 3D flash memory device having the same for breaking through the trade-off between the operation speed and the integration density of conventional flash memory devices.

An embodiment of the present invention provides a flash memory cell that includes a channel structure, a first gate, a second gate, a storage structure, a source line pillar and a bit line pillar. The channel structure is formed over a substrate. The first gate is formed adjacent to the channel structure. The second gate is separated from the first gate and the channel structure. The storage structure is adjacent to the channel structure. The source line pillar and the bit line pillar are respectively adjacent to opposite sidewalls of the channel structure. The first gate does not vertically overlap with the channel structure.

In addition, an embodiment of the present invention provides a 3D flash memory device that includes memory layers stacked separately by an insulating material on a substrate. Each of the memory layers includes memory cells that are arranged in an array. The memory cell includes a channel structure, a first gate, a second gate, a storage structure, a source line pillar and a bit line pillar. The channel structure is disposed in the memory layer. The first gate is disposed in the memory layer and adjacent to the channel structure. The second gate is disposed vertically on the substrate, and separated from the first gate and the channel structure. The storage structure is adjacent to the channel structure. The source line pillar and a bit line pillar are disposed vertically on the substrate, and respectively adjacent to opposite sidewalls of the channel structure. The first gate does not vertically overlap with the channel structure.

According to the embodiments, the operation speed and the integration density of the flash memory device can be improved.

### BRIEF DESCRIPTION OF THE DRAWINGS

FIG. 1 is a schematic perspective view of a 3D flash memory device, in accordance with some embodiments of the present disclosure.

FIG. 2 illustrates a schematic circuit diagram of FIG. 1.

FIG. 3 is a top view of adjacent memory cells in the same column of the memory layer of the 3D flash memory device.

FIG. 4A, FIG. 4B and FIG. 4C-1 illustrate a memory cell during operations in accordance with some embodiments of the present disclosure.

FIG. 4C-2 illustrates a memory cell during F-N erase operation in accordance with some embodiments of the present disclosure.

FIGS. 5A, 5B, 6, 7, 8, 9, 10, 11, 12, 13A, 13B, 14 and 15 illustrate intermediate stages of a method for forming a 3D flash memory device in accordance with some embodiments of the disclosure.

FIG. 16A to FIG. 16D illustrate intermediate stages of one applicable method for forming the heavily doped regions, the source line pillar and the bit line pillar of a 3D flash memory device, in accordance with some embodiments of the disclosure.

FIG. 17 is a top view illustrating a backfill material that includes the channel material and fills the inner space of the channel structure in accordance with some embodiments of the disclosure.

### DETAILED DESCRIPTION OF THE INVENTION

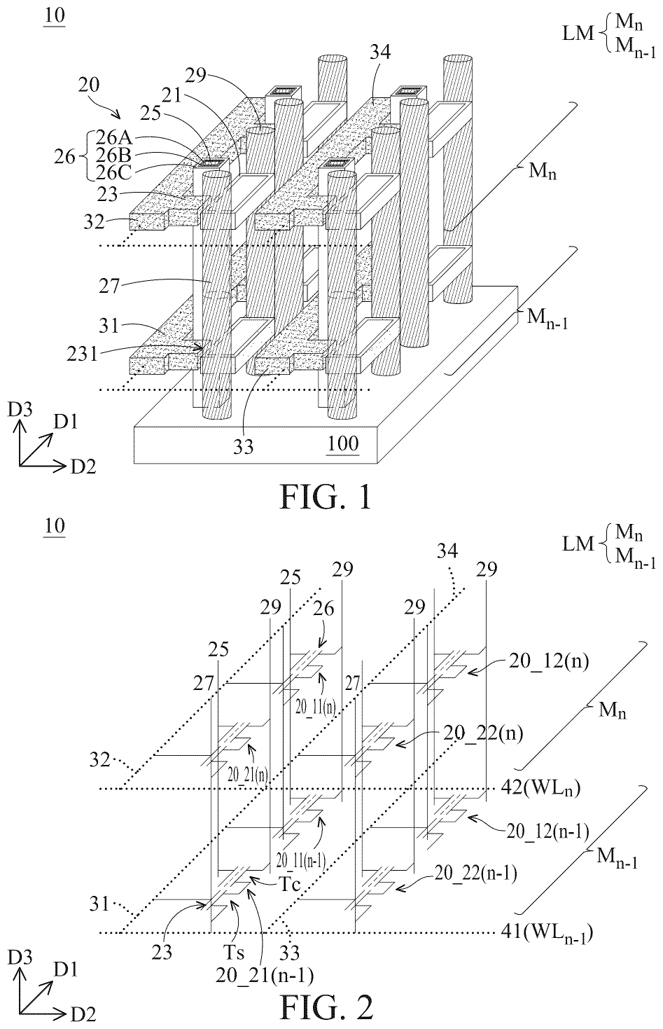

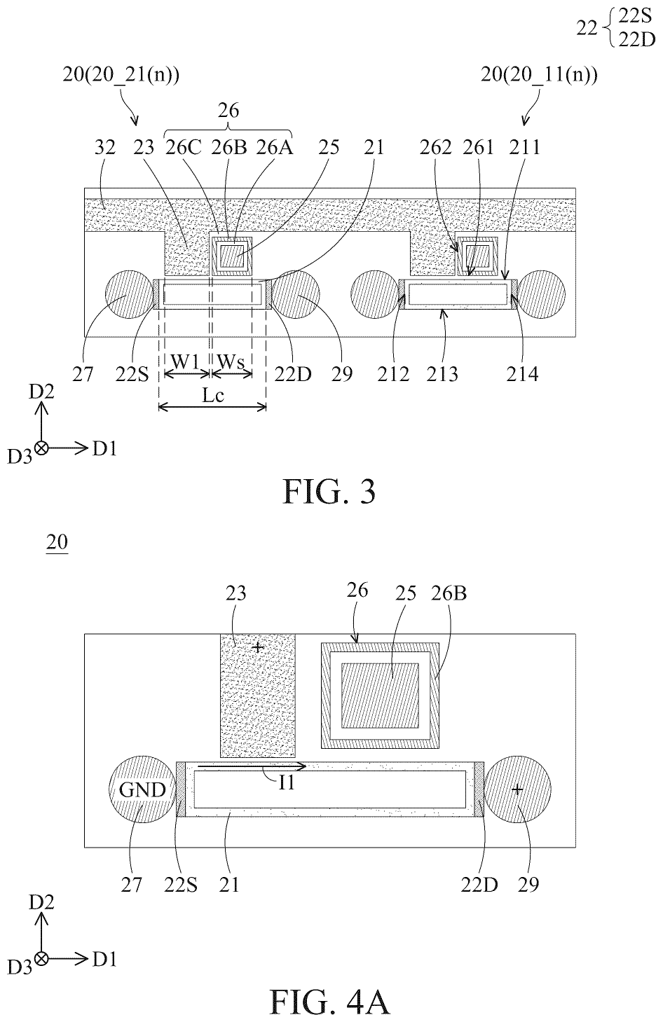

FIG. 1 is a schematic perspective view of a 3D flash memory device 10, in accordance with some embodiments of the present disclosure. FIG. 2 illustrates a schematic circuit diagram of the 3D flash memory device 10 in FIG. 1. The embodiments can be applied to flash memory devices, such as NOR flash memory device. A 3D split-gate flash memory device is used to illustrate a 3D flash memory device 10 of the embodiments.

In some embodiments, a 3D flash memory device 10 includes several memory layers LM stacked on a substrate 100 separately by insulating material. Each of the memory layers LM includes several memory cells that are arranged in an array. The memory layers LM can be planes defined by the first direction D1 and the second direction D2. The memory layers LM are at different layer levels in the third direction D3.

To simplify the diagram, two memory layers Mₙ and Mₙ₋₁ over the substrate 100 are depicted in FIG. 1 and FIG. 2, and four memory cells 20 in each of the memory layers are illustrated for exemplification. In addition, insulating material between the memory layers LM is not shown in FIG. 1, in order to clearly illustrate the relevant features of the memory cells 20.

In some embodiments, each of the memory cells 20 of the 3D flash memory device 10 is a split-gate memory cell. The memory cell 20 includes a channel structure 21, a first gate 23, a second gate 25, a storage structure 26, a source line pillar 27 and a bit line pillar 29. The channel structure 21 is formed in the memory layer LM, and serves as a channel region of the memory cell 20. When the memory cell 20 is operated, the generated current flows through the channel structure 21. The channel structure 21 may include polysilicon, indium-gallium-zinc oxide (IGZO), or another suitable channel material.

In some embodiments, the first gate 23 is formed in the memory layer LM, and may serve as the select gate of the memory cell 20. The first gate 23 does not vertically overlap with the channel structure 21. The first gate 23 is disposed adjacent to the channel structure 21, but not in contact with the channel structure 21. For example, the sidewall 231 of the first gate 23 is separated from the channel structure 21 by insulating material, such as oxide. The first gate 23 can be regarded as a word line of the memory cell 20. In addition, the first gate 23 may include doped polysilicon, metal-containing material such as tungsten (W), another suitable conductive material, or a combination thereof.

In some embodiments, the second gate 25 is disposed vertically on the substrate 100, and may serve as the control gate of the memory cell 20. The first gate 23 and the second gate 25 are disposed at the same side of the channel structure 21. The second gate 25 is separated from the first gate 23 and the channel structure 21. The storage structure 26 surrounds the second gate 25 and provides function of data storage.

The second gate 25 and the storage structure 26 of the memory cell 20 extend vertically to penetrate through the memory layers LM and the insulating material. As shown in FIG. 1, the second gate 25 can be a conductive pillar that extends in the third direction D3, and the storage structure 26 can be a hollow tube that surrounds the second gate 25. According to the embodiments, the second gate 25 is a common control gate for the group of memory cells that are stacked in a vertical direction with respect to the substrate 100. For example, the second gate 25 is common control gate for the memory cells 20_11(n) and 20_11(n−1) of a vertical string, as shown in FIG. 2.

In some embodiments, the storage structure 26 includes a charge-trapping layer that surrounds the second gate 25 and traps charges to store data. The charge trapping layer may be a nitride layer or a high-k dielectric layer. As shown in FIG. 1, the storage structure 26 may include a silicon oxide layer 26A in contact with the second gate 25, a silicon nitride layer 26B on the silicon oxide layer 26A, and another silicon oxide layer 26C on the silicon nitride layer 26B. When the memory cell 20 is in a programming operation, the silicon nitride layer 26B of the storage structure 26 serves as a charge-trapping layer that traps charges that are injected as hot electrons from the channel source side. Any one of two silicon oxide layers 26A and 26C may be used as a tunnel insulating layer and the other may be used as a blocking insulating layer.

In some embodiments, the source line pillar 27 and the bit line pillar 29 of the memory cell 20 are positioned on opposite sides of the channel structure 21. In addition, the source line pillar 27 and the bit line pillar 29 are disposed vertically on the substrate 100, and penetrate through the layers such as the memory layers LM and the insulating material.

According to the embodiments, the source line pillar 27 is a common source line for the group of memory cells that are stacked in a vertical direction with respect to the substrate 100. For example, a source line pillar 27 is common source line for the memory cells 20_21(n) and 20_21(n−1) of a vertical string, as shown in FIG. 2. Similarly, the bit line pillar 29 is a common bit line for the group of memory cells that are stacked in a vertical direction with respect to the substrate 100. For example, a bit line pillar 29 is common bit line for the memory cells 20_12(n) and 20_12(n−1) of a vertical string, as shown in FIG. 2.

The second gate 25, the source line pillar 27 and the bit line pillar 29 may include one or more metal materials, such as tungsten, another suitable conductive material, or a combination thereof. In an embodiment, the second gate 25, the source line pillar 27 and the bit line pillar 29 include the same material. For example, the second gate 25, the source line pillar 27 and the bit line pillar 29 are tungsten pillars. The second gate 25, the source line pillar 27 and the bit line pillar 29 can be formed by any known method, such as lithographic processes with patterned masks, etching processes for forming deep trenches, material filling processes, planarization processes and any suitable processes. The source line pillar 27 and the bit line pillar 29 can be formed simultaneously via the same manufacturing steps.

According to the embodiments, each of the memory cells 20 includes a select transistor Ts and a control transistor Tc coupled to the select transistor Ts, as shown in FIG. 2. The first gate 23 can be referred to as the select gate of the select transistor Ts, and the second gate 25 can be referred to as the control gate of the control transistor Tc. By the stacked configuration of the present invention, the cell integration can be increased.

In addition, at least some of the first gates 23 of the memory cells 20 in the same memory layer LM may be tied together to simplify word line decoding. In some embodiments, the memory cells 20 of each of the memory layers LM may be arranged in a matrix having several columns and rows. The first gates 23 of a group of memory cells 20 in each of the columns are electrically connected to each other, for example, by an interconnect line.

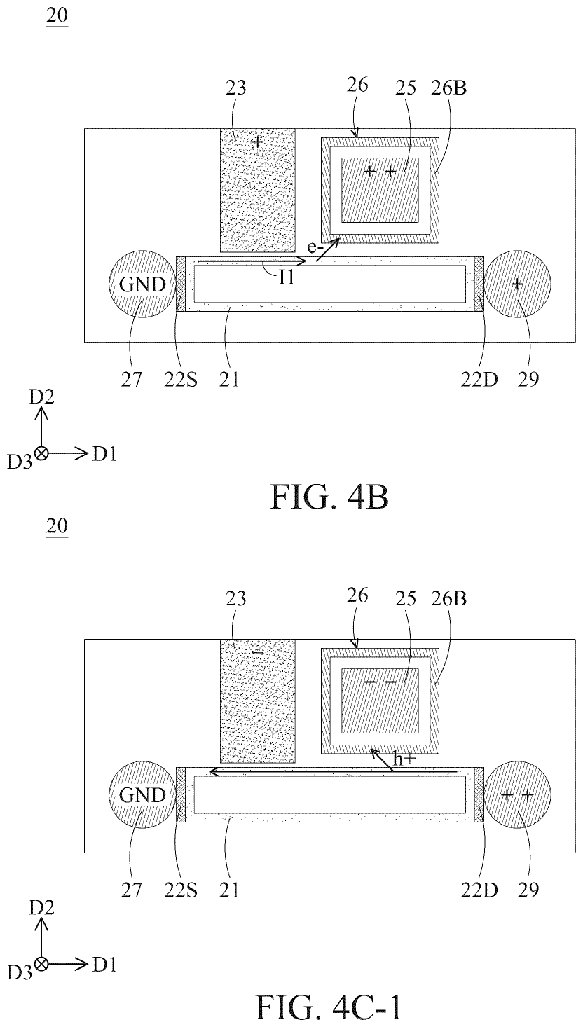

FIG. 3 is a top view of adjacent memory cells 20_11(n) and 20_21(n) in the same column of the memory layer Mₙ of the 3D flash memory device 10 in FIG. 1. In FIG. 3, configuration and arrangement of the relevant features of two adjacent memory cells of the same memory layer are depicted, wherein an interconnect line 32 connects the first gates 23 of the memory cells 20_11(n) and 20_21(n). Please refer to FIG. 1, FIG. 2 and FIG. 3.

In this exemplified embodiment, four memory cells in one memory layer can be arranged in a matrix having two columns and two rows. As shown in FIG. 2, the first gates 23 of the memory cells 20_11(n−1) and 20_21(n−1) in the first column of the memory layer Mₙ₋₁ are electrically connected to each other. Specifically, an interconnect line 31 that extends in the column direction (e.g. the first direction D1) electrically connect the first gates 23 of the memory cells 20_11(n−1) and 20_21(n−1) to form a common word line for the memory cells 20_11(n−1) and 20_21(n−1). The interconnect line 31 may be an individual wire that is physically in contact with one side of the corresponding first gates 23 of the memory cells in the first column, or may be a continuous portion extending from the corresponding first gates 23.

Similarly, in this exemplified embodiment, the first gates 23 of the memory cells 20_11(n) and 20_21(n) in the first column of the memory layer Mₙ are electrically connected by an interconnect line 32 that extends in the column direction, thereby forming a common word line for the memory cells 20_11(n) and 20_21(n). Also, an interconnect line 33 electrically connects the first gates 23 of the memory cells 20_12(n−1) and 20_22(n−1) in the memory layer Mₙ₋₁ to form a common word line for the memory cells 20_12(n−1) and 20_22(n−1). An interconnect line 34 electrically connects the first gates 23 of the memory cells 20_12(n) and 20_22(n) in the memory layer Mₙ to form a common word line for the memory cells 20_12(n) and 20_22(n). The interconnect lines 31, 32, 33 and 34 are parallel to each other.

In one embodiment, each of the interconnect lines 31, 32, 33 and 34 is simultaneously formed with the corresponding first gates 23 of the memory cells 20 in the same patterning process. That is, the first gates 23 and the interconnect lines 31, 32, 33 and 34 may be formed of the same conductive material.

In addition, in some embodiments, the interconnect lines that extend in the column direction (e.g. the first direction D1) in each of the memory layers LM are further connected by another conductive line to simplify word line decoding. For example, the interconnect lines 31 and 33 in the memory layer Mₙ₋₁ may be further electrically connected by the conductive line 41, as shown in FIG. 2. The interconnect lines 32 and 34 in the memory layer Mₙ may be further electrically connected by the conductive line 42. The conductive lines 41 and 42 are regarded as common word lines, such as WLₙ₋₁ and WLₙ, and may extend in the row direction (e.g., the second direction D2).

Specifically, referring to FIG. 3, the channel structure 21 includes the opposite sidewalls 211 and 213, and the opposite sidewalls 212 and 214. For example, the first gate 23 and the second gate 25 are adjacent to the sidewall 211 of the channel structure 21. The source line pillar 27 is adjacent to the sidewall 212, and the bit line pillar 29 is adjacent to the sidewall 214 of the channel structure 21.

In addition, in an embodiment, each of the memory cells 20 further includes heavily doped regions 22S and 22D on opposite sides of the channel structure 21, such as sidewalls 212 and 214. The heavily doped regions 22S and 22D respectively provides a lower contact resistance from the source line pillar 27 and the bit line pillar 29 to the channel structure 21. In an embodiment, the channel structure 21 and the heavily doped regions 22S and 22D have different conductivity types. For example, the channel structure 21 has the first conductivity type such as p-type, and the heavily doped regions 22S and 22D have the second conductivity type such as n-type. In addition, the channel structure 21 may be lightly doped, and the doping concentration of the channel structure 21 is less than the doping concentration of the heavily doped regions 22S and 22D. In this embodiment, the heavily doped regions 22S and 22D can be referred to as n+ regions.

Preferably, the storage structure 26 is disposed as close to the channel structure 21 as possible, thereby facilitating charge injection from the channel structure 21 to the charge-trapping layer (such as the silicon nitride layer 26B) of the storage structure 26. It should be noted that the second gate 25 has the shape of a square prism, a rectangular prism, a cylinder, or another suitable 3D shape. In some preferred embodiments, the second gate 25 is a square or rectangular pillar that is configured for the storage structure 26 in the proximity of the channel structure 21.

In addition, the second gate 25 and the storage structure 26 are disposed close to a corner that is defined by the first gate 23 and the channel structure 21, as viewed form the top of the memory layer. Specifically, in an example that an interconnect line (e.g. the interconnect line 32 in FIG. 3) connecting the first gates 23 of adjacent memory cells (e.g. 20_21(n) and 20_11(n)), the second gate 25 and the storage structure 26 are disposed in a region that is defined by the interconnect line 32, the first gate 23 and the sidewall 211 of the channel structure 21. According to some embodiments, the storage structure 26 has a first portion 261 and a second portion 262 that adjoins the first portion 261, as shown in FIG. 3. The first portion 261 is positioned between the channel structure 21 and the second gate 25. The second portion 262 is positioned between the first gate 23 and the second gate 25. Specifically, the first portion 261 of the storage structure 26 extends along the sidewall 211 of the channel structure 21, and the second portion 262 of the storage structure 26 extends along a sidewall of the first gate 23.

In addition, the dimensions of the first gate 23 and the storage structure 26 may be designed based on the dimension of the channel structure 21. For example, a total width (in the first direction D1) of the first gate 23 and the storage structure 26 may be less than, proximate to, or slightly greater than the length (in the first direction D1) of the channel structure 21. Specifically, in this exemplified embodiment, as shown in FIG. 3, the sidewall 211 or the sidewall 213 has the length Lc in the first direction D1. The first gate 23 has a width W1 in the first direction D1. The storage structure 26 has a width Ws in the first direction D1. The length Lc is greater than the sum of the width W1 of the first gate 23 and the width Ws of the storage structure 26.

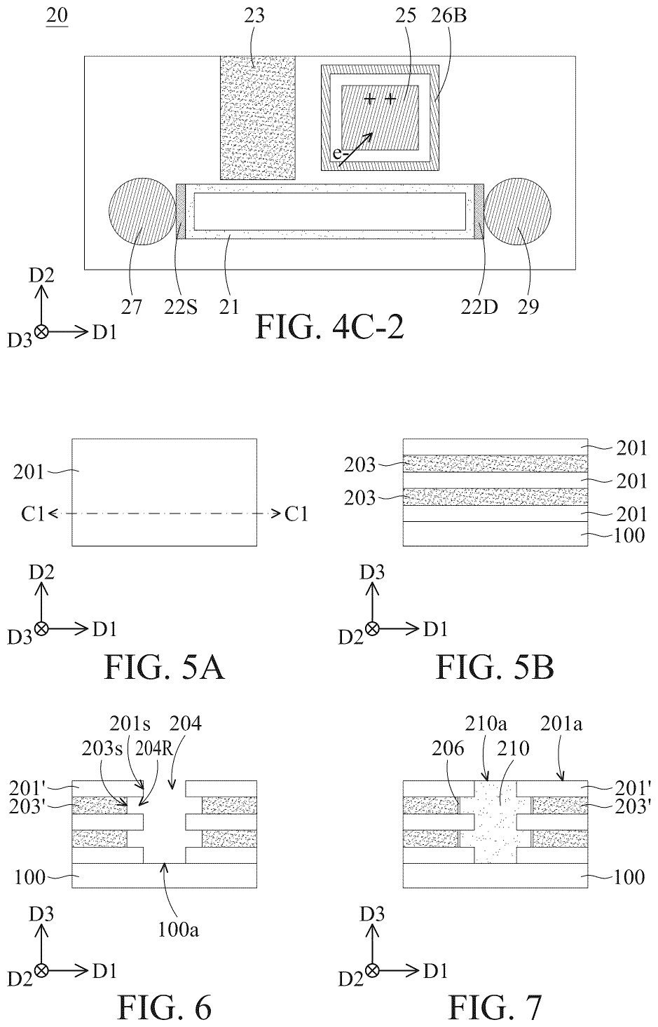

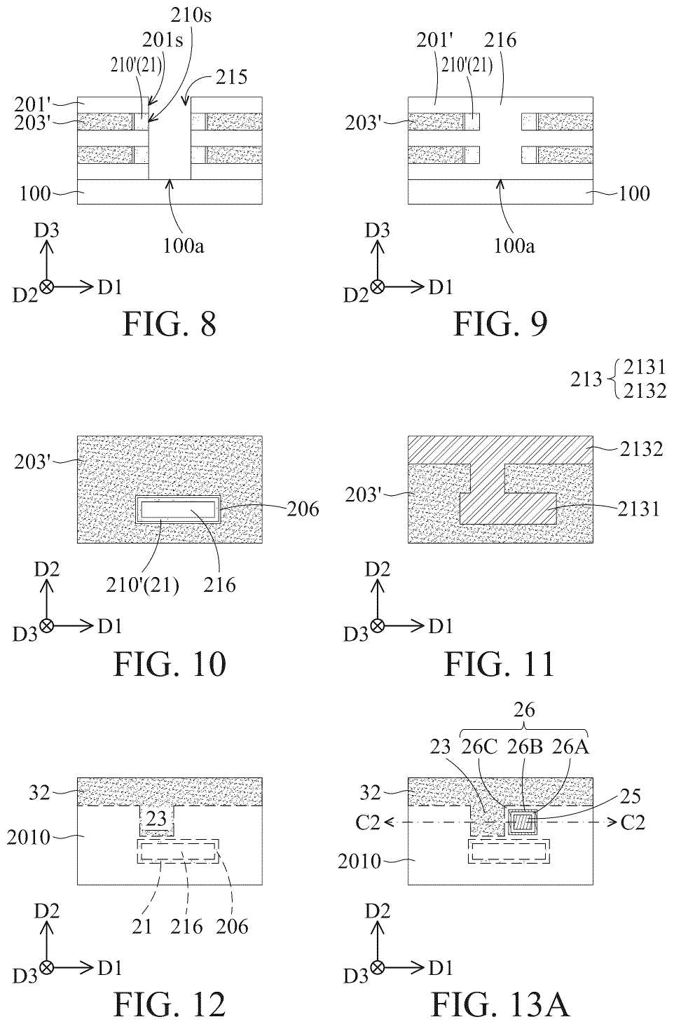

FIG. 4A, FIG. 4B and FIG. 4C-1 illustrate a memory cell during operations in accordance with the present disclosure. The source line pillar 27 and the bit line pillar 29 can be regarded as source and drain of the memory cell 20. The memory cell 20 may be programmed by hot carrier injection (also known as “hot electron injection”) from the source-side. The first gate 23 acts as the select gate of the memory cell 20, which enables current to flow.

In an embodiment, as shown in FIG. 4A, when positive bias are applied to the first gate 23 and the bit line pillar 29, and the source line pillar 27 is grounded, the memory cell 20 is in an on-state. A current I1 flows from the source side (i.e. the source line pillar 27) toward the drain side (i.e. the bit line pillar 29) in the channel structure 21.

In an embodiment, as shown in FIG. 4B, when the memory cell 20 is programmed by hot carrier injection, while the source line pillar 27 is grounded, positive bias are applied to the second gate 25, the first gate 23 and the bit line pillar 29. The hot electrons e⁻ are injected into the storage structure 26 and trapped in the silicon nitride layer 26B.

According to some embodiments, the memory cell 20 can be erased by hot hole injection for higher speed, and alternatively by Fowler-Nordheim (F-N) tunneling injection for preventing over-erase problem.

In an embodiment, as shown in FIG. 4C-1, when the memory cell 20 is erased by hot hole injection, a negative bias is applied to the first gate 23, a greater negative bias is applied to the second gate 25, a greater positive bias is applied to the bit line pillar 29 (drain) and the source line pillar 27 is grounded. Hot holes are injected into the charge-trapping layer (such as the silicon nitride layer 26B) of the storage structure 26 to neutralize the electrons that are already trapped.

In an embodiment, as shown in FIG. 4C-2, when the memory cell 20 is erased by F-N tunneling injection, a greater positive bias is applied to the second gate 25 while the others are floating. That is, no bias is applied to the first gate 23, the source line pillar 27 and the bit line pillar 29. The trapped electrons are pulled out of the charge-trapping layer (such as the silicon nitride layer 26B) into the second gate 25 to be carried away. As the charge is reduced, the electric field is reduced. Therefore, an erase operation can be performed with self-limiting function to prevent the memory cell 20 being overly erased.

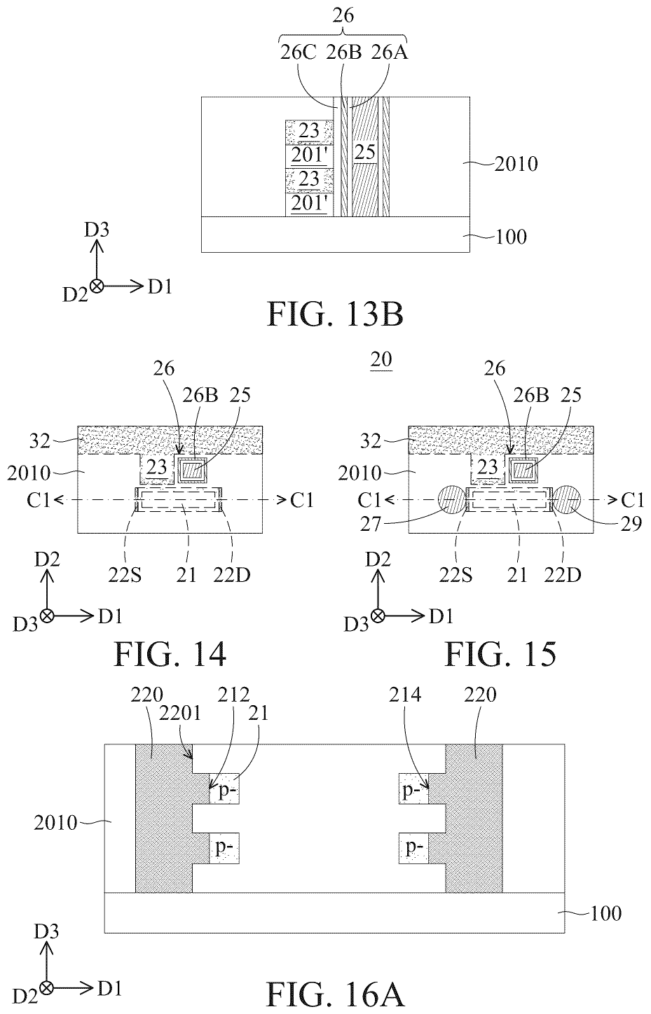

FIG. 5A to FIG. 15 illustrate intermediate stages of a method for forming a 3D flash memory device 10 in accordance with some embodiments of the disclosure. FIG. 5B is a cross-sectional view of an intermediate stage of a 3D flash memory device 10 taken along line C1-C1 in FIG. 5A. FIG. 13B is a cross-sectional view of an intermediate stage of a 3D flash memory device 10 taken along line C2-C2 in FIG. 13A.

Referring to FIG. 5A and FIG. 5B, several insulating layers 201 and conductive layers 203 are alternately stacked on a substrate 100. In some embodiments, the substrate 100 may be a semiconductor substrate, such as a bulk semiconductor substrate, a semiconductor-on-insulator (SOI) substrate, or the like. The substrate 100 may be undoped or doped with p-type or n-type dopants. The insulating layers 201 may include oxide or another suitable insulating material. The conductive layers 203 may include one or more semiconductor materials with p-type or n-type dopants, or another suitable conductive material. In some embodiments, the insulating layers 201 are silicon oxide layers, and the conductive layers 203 are p+ polysilicon.

In some embodiments, the insulating layers 201 may be formed by a chemical vapor deposition (CVD) process such as a low-pressure CVD process, a plasma enhanced CVD process, or a combination thereof. The conductive layers 203 may be formed by a CVD process, a physical vapor deposition (PVD) process, or a combination thereof. The numbers of the insulating layers 201 and the conductive layers 203 may be adjusted depending on the required characteristics of the actual product of the 3D flash memory device 10.

Referring to FIG. 6, in some embodiments, a trench 204 is then formed through the laminated insulating layers 201 and the conductive layers 203 until the top surface 100a of the substrate 100 is exposed. The trench 204 may be formed by one or more etching processes. In some embodiments, the trench 204 may be formed by vertically removing a portion of the laminated insulating layers 201 and the conductive layers 203 to expose the substrate 100, followed by laterally recessing the conductive layers 203 to form the recesses 204R each on the remaining conductive layer 203′ and between the remaining insulating layers 201′.

Next, referring to FIG. 7, in some embodiments, a gate dielectric layer 206 is formed on the exposed sidewalls of the remaining conductive layers 203′. The gate dielectric layer 206 may be formed by using a CVD or an atomic layer deposition (ALD). The insulating layers 201 and the gate dielectric layer 206 may include the same insulating material such as silicon oxide.

In some embodiments, after the gate dielectric layer 206 is formed on the exposed sidewalls of the remaining conductive layers 203′, a channel material is deposited to fill the trench 204, including the recesses 204R. A planarization process, such as a chemical mechanical polishing (CMP) process, is performed to expose the top surface 201a of the insulating layer 20′, thereby forming a channel material pillar 210 in the trench 204. The top surface 201a of the insulating layer 20′ may be coplanar with the top surface 210a of the channel material pillar 210. The channel material pillar 210 may include semiconductor material with suitable type of dopants. In some embodiments, the channel material pillar 210 includes polysilicon with p-type dopants. In some embodiments, the channel material pillar 210 and the conductive layers 203′ include the same material. The doping concentration of the conductive layers 203′ is greater than the doping concentration of the channel material pillar 210. For example, the conductive layers 203′ are p+ polysilicon layers, and the channel material pillar 210 is a p− polysilicon pillar.

Next, referring to FIG. 8, in some embodiments, a portion of the channel material pillar 210 is removed, such as by etching, to form a trench 215 that exposes the top surface 100a of the substrate 100. The remaining portions 210′ of the channel material pillar 210 that fill the recess 204R form the channel structures 21 of the 3D flash memory device 10. That is, the remaining portions 210′ of the channel material pillar 210 in the same memory layer are portions of a ring when it is viewed from the top. After the trench 215 is formed, the vertical sidewall 201s of the insulating layers 201′ are substantially aligned with the inner sidewall 210s of the remaining portions 210′ of the channel material pillar 210 (i.e., the channel structures 21).

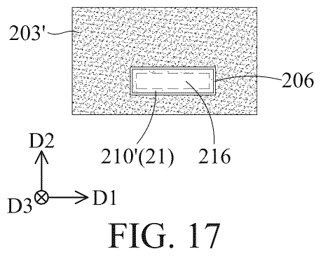

Referring to FIG. 9, a backfill material 216 is formed to fully fill the trench 215. In some embodiments, to improve the convenience of manufacturing, the backfill material 216 may include insulating material such as oxide. Therefore, as shown in FIG. 10, the channel structure 21 is formed as a channel ring (namely, the remaining portions 210′ of the channel material pillar 210) surrounding the backfill material 216 made of insulating material. The backfill material 216 may be formed by using a CVD process, a PVD process, or an ALD process. In some embodiments, the backfill material 216 and the insulating layers 201 include the same insulating material, such as silicon oxide, so that no interface exists between the backfill material 216 and the insulating material 201′. However, in an alternative embodiment, as shown in FIG. 17, the backfill material 216 may include the channel material, the channel structure 21 is formed as a channel sheet.

In some embodiments, after the channel structures 21 are formed in its horizontal planes, the first gate 23, the storage structure 26 and the second gate 25 are formed subsequently.

Referring to FIG. 10, after the backfill material 216 fills the trench 215, the upper insulating material 201 and a portion of the backfill material 216 are removed, such as by a back etching process or a CMP process, to expose the underlying conductive layer 203′ and the channel structure 21. FIG. 10 is a top view illustrating that the backfill material 216 fills the inner space of the channel structure 21, and the gate dielectric layer 206 surrounds the channel structure 21. The channel structure 21, the gate dielectric layer 206 and the conductive layer 203′ form a layer that is parallel to the top surface 100a of the substrate 100.

Referring to FIG. 11, in some embodiments, a word line mask 213 is provided to define positions of a first gate 23 of each memory cell and the interconnect line 32 that connects the first gates 23 of the memory cells. The word line mask 213 includes a first portion 2131 and a second portion 2132. The first portion 2131 covers the channel structure 21 and defines the position of the first gate 23 that is formed subsequently. As shown in FIG. 11, the first portion 2131 has a T-shape and connects the second portion 2132. The second portion 2132 defines the position of the interconnect line 32 that is formed subsequently. The second portion 2132 extends in the first direction D1 and connects another first portions 2131 for defining first gates of adjacent memory cells in the same column of an array of memory cells. Please also refer to FIG. 1 to FIG. 3.

Referring to FIG. 12, in some embodiments, a patterning process is performed to remove the portions of the laminated layers (including the conductive layers 203′ and the insulating layers 201′) that are not covered by the word line mask 213. The remaining portions of the conductive layers 203′ form the first gates 23 and the interconnect lines 32 stacked over the substrate 100. Accordingly, the top surface of the first gate 23 is coplanar with the top surface of the channel structure 21. Then, after the patterning process is completed, the word line mask 213 is removed by a suitable method, such as by etching, stripping or ashing. Then, the left space that is formed by upon removal of the portions of the laminated layers is backfilled with an insulating fill material 2010, such as silicon oxide. The insulating fill material 2010 may be excessively deposited to cover the underlying components including the first gates 23, the interconnect lines 32 and the channel structure 21. A planarization process, such as CMP, may be performed on the insulating fill material 2010 to form a flat top surface on the insulating fill material 2010. In this embodiment, the insulating fill material 2010 and the gate dielectric layer 206 may include the same insulating material, such as silicon oxide, so that no interface exists between the insulating fill material 2010 and the gate dielectric layer 206. In some embodiments, the remaining insulating layers 201′ and the insulating fill material 2010 can be collectively called as the insulating material.

Referring to FIG. 13A and FIG. 13B, in some embodiments, the second gate 25 and the storage structure 26 are formed adjacent to the first gate 23 and the channel structure 21. In one exemplified embodiment, an opening (not shown) is formed adjacent to the first gate 23. The opening is formed vertically to penetrate the insulating fill material 2010 and expose the substrate 100. Then, a silicon oxide layer 26A, a silicon nitride layer 26B and another silicon oxide layer 26C of the storage structure 26 and a conductive pillar that acts as second gate 25 are formed in the opening in sequential order. The silicon oxide layer 26C and the conductive pillar may be formed by filling silicon oxide into a space surrounded by the silicon nitride layer 26B, forming a vertical hole (not shown) that has the same shape and size of a predetermined second gate 25 in the silicon oxide layer, and then filling the vertical hole with a conductive material to form the second gate 25. As shown in FIG. 13B, the second gate 25 is a vertical conductive pillar that extends in the third direction D3. The silicon oxide layer 26A and the silicon nitride layer 26B of the storage structure 26 are hollow tubes that surround the second gate 25 on the substrate 100.

In addition, the insulating fill material 2010 and the silicon oxide layer 26C may include the same insulating material, so that no interface exists between the insulating fill material 2010 and the silicon oxide layer 26C.

Referring to FIG. 14, in some embodiments, two heavily doped regions 22S and 22D are formed at the opposite sides of the channel structure 21 in each of the memory cells.

Referring to FIG. 15, in some embodiments, a source line pillar 27 and a bit line pillar 29 are formed vertically on the substrate 100. The source line pillar 27 is formed in contact with the heavily doped region 22S in one of the memory cells of the memory layers LM (FIG. 1). Similarly, the bit line pillar 29 is formed in contact with the heavily doped region 22D in one of the memory cells of the memory layers LM. The channel structure 21, the gate dielectric layer 206, the first gate 23, the second gate 25, doped regions 22S and 22D, source line pillar 27 and a bit line pillar 29 that are embedded in the insulating material constitute the memory cell 20.

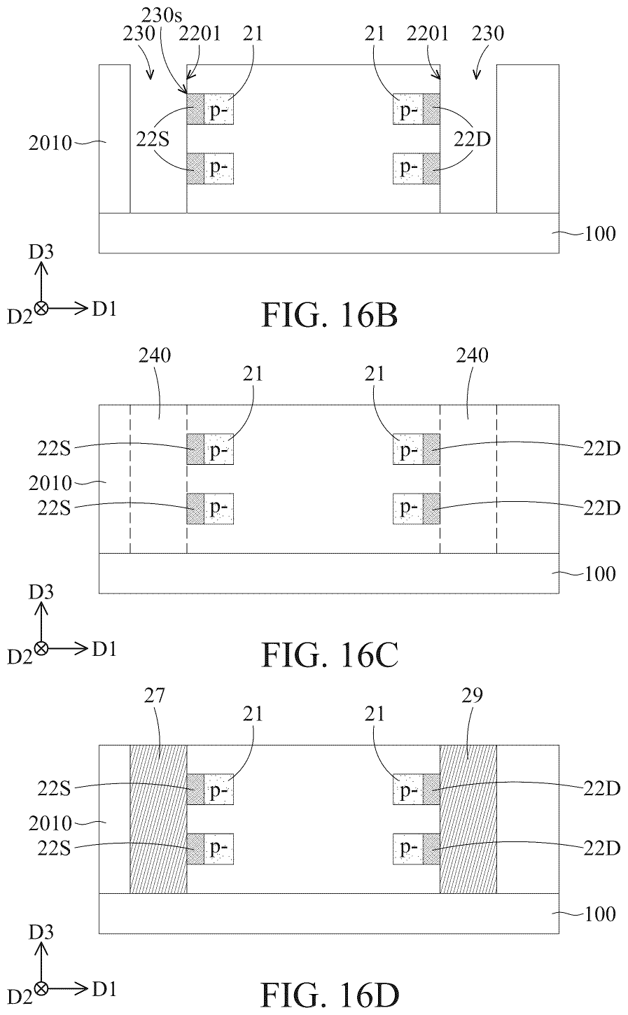

FIG. 16A to FIG. 16D illustrate intermediate stages of one applicable method for forming the heavily doped regions 22S and 22D, the source line pillar 27 and the bit line pillar 29 of a 3D flash memory device 10, in accordance with some embodiments of the disclosure. FIG. 16A to FIG. 16D are cross-sectional views of intermediate stages of the 3D flash memory device 10 taken along line C1-C1 in FIG. 14 and FIG. 15.

Referring to FIG. 16A, in some embodiments, two vertical trenches (not shown) that are adjacent to the channel structures 21 are formed by removing portions of the insulating fill material 2010. The vertical trenches may be formed by one or more etching processes. In some embodiments, an isotropic etching process may selectively etch the channel structures 21 (e.g., p+ polysilicon layers) at a higher etching rate than the insulating fill material 2010. After the p+ polysilicon rings are recessed, an n+ polysilicon material 220 is deposited on the insulating fill material 2010 to fill the vertical trenches. A planarization process, such as CMP, is then performed on the n+ polysilicon material 220 until the insulating fill material 2010 is exposed. As a result, the sidewalls 212 of the channel structures 21 are laterally recessed from the interface 2201 between the n+ polysilicon material 220 and the insulating fill material 2010.

Next, referring to FIG. 16B, in some embodiments, excess portions of the n+ polysilicon material 220 are removed, such as by etching. The remaining portions of the n+ polysilicon material 220 form the heavily doped regions 22S and 22D at the sidewalls 212 and 214 of the channel structures 21. For example, portions of the insulating fill material 2010 are removed to form trenches 230. The inner sidewalls 230s of the trenches 230 are substantially aligned with the interface 2201 between the n+ polysilicon material 220 and the insulating fill material 2010.

Next, referring to FIG. 16C, in some embodiments, the trenches 230 are filled with an insulating material 240. In addition, the exposed sidewalls of the heavily doped regions 22S and 22D in the trenches 230 are covered by the insulating material 240. In some embodiments, the insulating material 240 and the insulating fill material 2010 include the same insulating material, such as silicon oxide, so that no interface exists between the insulating material 240 and the insulating fill material 2010.

Next, referring to FIG. 16D, in some embodiments, portions of the insulating fill material 2010 are removed, such as by etching, to form two vertical holes (not shown) that have the same shapes and sizes of the source line pillar 27 and the bit line pillar 29 in the insulating fill material 2010. Then, a conductive material, including one or more metal materials (such as tungsten) or another suitable conductive material, is deposited on the insulating fill material 2010 to fill the vertical holes. The conductive material may be deposited by a CVD process such as a metalorganic CVD (MOCVD) process, a PVD process such as a vacuum evaporation process or a sputtering process, or a combination thereof. Then, excess portions of the conductive material are removed, thereby forming a source line pillar 27 and the bit line pillar 29 in the vertical holes. The source line pillar 27 and the bit line pillar 29 are adapted to contact the heavily doped regions 22S and 22D (e.g., n+ regions) at two second opposite sides of the channel structure 21.

In the 3D flash memory device 10 of some embodiments, the word lines of different memory layers LM are positioned at different layer levels, while the second gate 25, the source line pillar 27 and the bit line pillar 29 penetrate through the layers that are vertically stacked over the substrate 100. According to the embodiments, the structural configuration of those related features increases integration density of the memory cells of a 3D flash memory device 10, in particular to a 3D NOR flash memory device. For example, the first gate 23 and the second gate 25 are disposed at one side of the channel structure 21, which makes arrangement of the gate features more compact in a lateral region. In addition, several laminated layers can be etched at once, which means less etching steps are used. The layer-separated films can be formed by recessing process. The word lines of the memory cells of the 3D flash memory device 10 can be formed in the same process step(s). The source line pillars 27 and the bit line pillars 29 of the 3D flash memory device can be formed in the same process step(s). In addition, the 3D flash memory device 10 of some embodiments provides easier word line decoding to simplify the operations. In addition, a 3D split-gate flash memory device with increased integration density and more efficient operations can be provided in accordance with some embodiments. For example, the 3D split-gate flash memory device of the embodiments has more efficient programming, more efficient erasing and more retention immunity than a conventional stacked-gate memory device.

Besides, the 3D flash memory device of the embodiments has several advantages on the aspects of environmental friendly. For example, compared to a 2D memory device, the memory device of the embodiments is built up as a 3D structure with higher integration density, and larger features (e.g. about 100 nm) are applicable to be formed in the 3D flash memory device of the embodiments. Accordingly, there is no need to form the 3D flash memory device of the embodiments by using advanced lithography processes, such as immersion lithography. The 3D flash memory device of the embodiments can be formed by using typical lithography processes that requires much less power than advanced lithography processes. In addition, according to the aforementioned descriptions, less etching steps are required for forming the 3D flash memory device of the embodiments, consequently smaller amounts of etchants are used during device fabrication. The etchants contain fluorocarbons that contribute to global warming and are potentially hazardous to environment. In addition, the 3D flash memory device of the embodiments can be erased by F-N tunneling injection, which prevents occurrence of over erase of the memory cells. Accordingly, the 3D flash memory device of the embodiments has characteristics with a higher endurance and a longer lifetime, thereby reducing unnecessary waste of environmental resources.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory cell, comprising:
a channel structure formed over a substrate;
a first gate formed adjacent to the channel structure;
a second gate separated from the first gate and the channel structure;
a storage structure adjacent to the channel structure; and
a source line pillar and a bit line pillar respectively adjacent to opposite sidewalls of the channel structure,
wherein the first gate does not vertically overlap with the channel structure.

2. The flash memory cell as claimed in claim 1, wherein the storage structure includes a charge-trapping layer surrounding the second gate, and the channel structure is formed as a channel ring.

3. The flash memory cell as claimed in claim 2, wherein the charge-trapping layer is separated from the first gate and the second gate, and the first gate and the second gate are disposed at the same side of the channel structure.

4. The flash memory cell as claimed in claim 1, further comprising an insulating material formed over the substrate, wherein the storage structure, the second gate, the source line pillar and the bit line pillar are disposed vertically on the substrate and penetrate through the insulating material.

5. The flash memory cell as claimed in claim 1, wherein the first gate and the second gate respectively function as a select gate and a control gate of a split-gate memory cell, and the top surface of the first gate is coplanar with the top surface of the channel structure.

6. The flash memory cell as claimed in claim 1, wherein the first gate and the second gate are adjacent to a sidewall of the channel structure adjoining the opposite sidewalls of the channel structure.

7. The flash memory cell as claimed in claim 6, wherein the storage structure comprises:
a first portion extending along the sidewall of the channel structure; and
a second portion extending between the first gate and the second gate.

8. The flash memory cell as claimed in claim 1, further comprising:
heavily doped regions respectively at the opposite sidewalls of the channel structure,
wherein the source line pillar and the bit line pillar connect to the channel structure by the heavily doped regions.

9. The flash memory cell as claimed in claim 1, wherein the storage structure includes a charge-trapping layer surrounding the second gate, and the channel structure is formed as a channel sheet.

10. A three-dimensional (3D) flash memory device, comprising:
a plurality of memory layers stacked separately by an insulating material on a substrate, wherein each of the memory layers comprises a plurality of memory cells that are arranged in an array, and each of the memory cells comprises:
a channel structure disposed in the memory layer;
a first gate disposed in the memory layer and adjacent to the channel structure;
a second gate disposed vertically on the substrate, and separated from the first gate and the channel structure;
a storage structure adjacent to the channel structure; and
a source line pillar and a bit line pillar disposed vertically on the substrate, and respectively adjacent to opposite sidewalls of the channel structure,
wherein the first gate does not vertically overlap with the channel structure.

11. The 3D flash memory device as claimed in claim 10, wherein the storage structure includes a charge-trapping layer surrounding the second gate, and the channel structure is formed as a channel ring.

12. The 3D flash memory device as claimed in claim 10, wherein
the second gate is a common control gate for a group of the memory cells that are stacked in a vertical direction with respect to the substrate,
the source line pillar and the bit line pillar are respectively a common source line and a common bit line for a group of the memory cells that are stacked in the vertical direction with respect to the substrate.

13. The 3D flash memory device as claimed in claim 10, wherein the memory cells of each of the memory layers are arranged in a matrix that has columns and rows, and the first gates of a group of the memory cells in each of the columns are electrically connected to each other.

14. The 3D flash memory device as claimed in claim 13, wherein
the first gates of the group of memory cells in each of the columns are electrically connected by an interconnect line extending in a column direction,
the interconnect lines extending in the column direction in each of the memory layers are parallel to each other, and a conductive line is connected to the interconnect lines.

15. The 3D flash memory device as claimed in claim 11, wherein the charge-trapping layer is separated from the first gate and the second gate, and the first gate and the second gate are disposed at the same side of the channel structure.

16. The 3D flash memory device as claimed in claim 10, wherein the first gate and the channel structure in each of the memory cells are formed in one of the memory layers and extend parallel to the substrate.

17. The 3D flash memory device as claimed in claim 10, wherein the storage structure, the second gate, the source line pillar and the bit line pillar are disposed vertically on the substrate and penetrate through the insulating material.

18. The 3D flash memory device as claimed in claim 10, wherein each of the memory cells further comprises:
heavily doped regions respectively at the opposite sidewalls of the channel structure,
wherein the source line pillar and the bit line pillar connect to the channel structure by the heavily doped regions.

19. The 3D flash memory device as claimed in claim 10, wherein the first gate and the second gate respectively function as a select gate and a control gate of a split-gate memory cell, and the top surface of the first gate is coplanar with the top surface of the channel structure.

20. The 3D flash memory device as claimed in claim 10, wherein the storage structure includes a charge-trapping layer surrounding the second gate, and the channel structure is formed as a channel sheet.
